(19) United States
(12) Patent Application Publication
(10) Pub. No.: US 2021/0103171 A1
(43) Pub. Date: Apr. 8, 2021

(54) Incorporation of solar cells into LCD screens of mobile electronic devices

(71) Applicant: Ariel Efrati, Jerusalem (IL)

(72) Inventor: Ariel Efrati, Jerusalem (IL)

(21) Appl. No.: 17/062,579

(22) Filed: Oct. 3, 2020

Related U.S. Application Data
(60) Provisional application No. 62/910,471, filed on Oct. 4, 2019.

(51) Int. Cl. G02F 1/133; H02S 10/40; H02S 40/38; H02J 7/35

(52) U.S. Cl. CPC G02F 1/13306; H02S 10/40; G02B 6/0011; H02J 7/35; G02F 2001/13324; H02S 40/38

(57) ABSTRACT

This invention enables the solar charging of mobile electronic devices through LCD screens. High power efficiency photovoltaic panels utilize the light deflecting properties of Edge-lit LCD screens to produce electrical energy for the recharging of the batteries of the devices. Smartphones; laptop computers; tablets; e-readers, mobile phones, among other mobile devices are covered by the scope of the current invention. The addition of photovoltaic cells, according to the invention, should not change significantly the appearance of the devices or manufacturing costs.

### FIELD OF THE INVENTION

The present invention relates to the incorporation of photovoltaic cells into the LCD screens of mobile electronic devices such as smartphones.

### BACKGROUND OF THE INVENTION

Mobile electronic devices are mostly powered by batteries. Such batteries' capacity design is limited weight and volume. For example, the batteries of most smartphones possess a capacity of 5000 mAh, and the average user has to recharge the device approximately every day. Solar power is an inexhaustible source of green energy and can be used for the recharging of mobile devices. During traveling or in cases when the batteries completely discharge, such powering, without an available electrical grid can be extremely valuable as well.

Currently most mobile electronic devices do not use solar panels as a source of energy. Moreover, a combination of solar panels on the surface of the devices is impractical for several reasons. These reasons include first and foremost the change of the design of the instrument. User comfort and even the main functionality of the device can be compromised by such a design change. Large solar panels will additionally add weight to the device and additional glass surface area.

### SUMMARY OF THE INVENTION

It is therefore an object of the current invention to disclose an alternative method for the solar charging of mobile electronic devices. Such mobile electronic devices include and are not limited to smartphones; laptop computers, electronic watches, tablets; e-readers, and mobile phones. The current invention focuses on the solar irradiation flux through the screen of mobile devices which includes a light guide plate, such as LCD screens. These screens include all LCD technologies as QLED (quantum-dot light-emitting diode), AMOLED (active-matrix organic LED), TN (twisted nematic), VA (vertical alignment), IPS (in plane switching), PVA (patterned vertical alignment) and similarly related technologies.

A core object of the current invention is to disclose a mobile electronic device with a screen, which possesses the functionality of wide spectrum absorption by low band gap solar cells. As LCD screens do not generate light, but merely manipulate the intensity and wavelengths that go through the LCD module, they require other means of illumination from the back. Edge-lit backlight LCDs contain light sources on the sides of the screen and use a light guide plate (LGP). This is a plate, usually made from an acrylic transparent substance, such as PMMA (poly-methyl methacrylate) and polystyrene copolymer matrix, with etched patterns. It serves as a means to redirect the light from the LEDs, which are positioned on the edges, uniformly as possible, towards the whole face of the plate and out towards the LCD module on top. Typically, two additional layers are added on top of the LGP, a diffusing layer meant to distribute the light more evenly, and a prism sheet. The latter transmits mostly light which is directed at desired angles towards the screen and reflects back the rest of the radiation. An additional reflector sheet, on the other side of the LGP, retrieves the photons on the direction opposite to the liquid crystals layer, thereby saving a substantial amount of energy. According to this invention, solar panels will be positioned on the side edges of the screen, and may cover any part of the surface which is not occupied by the LEDs. These panels active area will face about these side edges. Upon illumination of the screen from the top, as light behaves similarly on both directions of travel, the LGP, diffusing layer, prism sheet and reflector sheet will redirect the light. A substantial amount of it is expected to reach the side edges of the screen, where it will be absorbed, in part, by these solar panels and recharge the battery. These solar panels can operate when the device and screen are running as well. A part of the light will transduce through the LCD display to the LGP (possibly with the help of the other mentioned layers such as the reflector sheet) and finally will be absorbed by the solar panels.

When no voltage is applied on the liquid crystals (the screen is off, or the opposite for some technologies such as IPS), they will self-assemble in a twisted nematic configuration, which will rotate the polarization of the light which has passed the top polarizer (usually by 90 degrees), enabling it to pass through the bottom polarizer and reach the LGP at higher success probability. It must be emphasized that should a photon enter the screen at the exact same point and opposite direction as one emitted from the device, it would travel precisely the same path going the opposite way and reach the LED panel itself. Since this is statistically improbable, a significant amount of light entering the screen will be able to reach the solar panels to the sides of the LGP instead. These solar cells can be of any type, and should mainly focus on low band gap-high power conversion efficiency solar cells as silicon, GaAs or CIGS (copper indium gallium selenide) based panels, and may include multijunction configurations. Finally, it should be noted that the addition of the LGP to a screen, especially for the purpose of entering solar panels to its sides by this configuration is possible as well. An example of a device with Edge-lit backlight LCD screen, incorporated with six low band gap solar panels to the sides of the screen, is illustrated in FIG. 1.

Therefore, is a core object of the present invention to provide an alternative concept of solar cells integration for the charging of cellular phones, smartphones, e-readers, tablets, laptop computers and other portable electronic devices which include a screen. Solar cells of any type, and mostly low band gap-high power conversion efficiency ones, can be integrated and positioned to the sides of the screen.

A further object of the present invention is to provide an alternative for electrical grid charging of cellular phones; smartphones; tablets; e-readers; laptop computers and other portable electronic devices which include a screen, during traveling and as a means for emergency rescue communications.

More characteristics, advantages, operation methods will be evident as a result of the following claims and the detailed drawings of the inventions. A brief description of the drawings and a detailed one shell be followed by the claims of the current invention.

### BRIEF DESCRIPTION OF THE FIGURES

The believed key elements of the invention are described in the following drawings and description. This is furnished by a way of example. It should be noticed that these drawings are for illustrations and elucidation intents only. These should not define the limits of the scope of the current invention.

FIG. 1 illustrates the detached layers of the edge-lit backlight screen of a self-rechargeable electronic device with solar cells;

FIG. 2 is a top view of the screen described in FIG. 1; and

FIG. 3 corresponds to the three light dispersing layers of an edge-lit LCD screen, incorporating wide absorbance solar cells.

### DETAILED DESCRIPTION OF THE ILLUSTRATED EMBODIMENTS

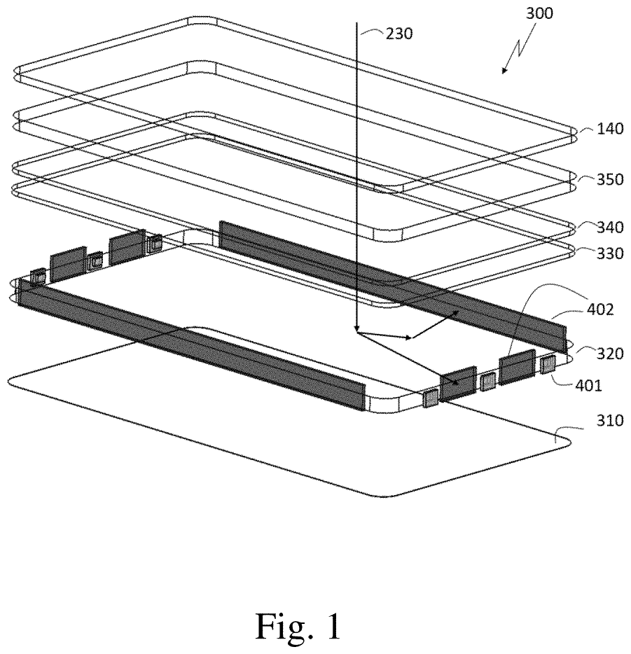

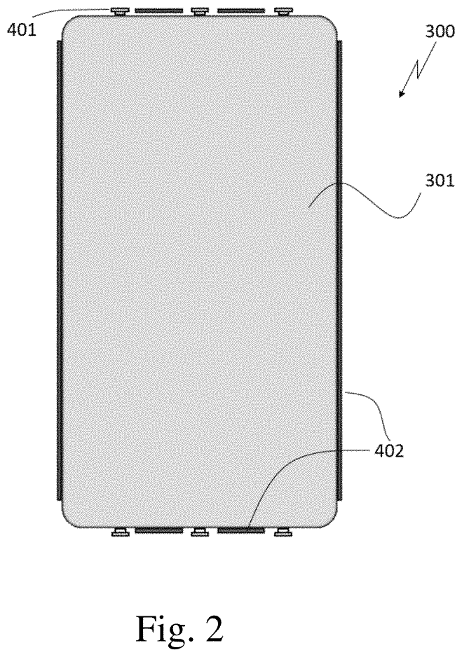

FIG. 1 displays, in a spread-out manner, the design of an edge-lit LCD screen with a solar energy utilization functionality 300. The screen comprises a LGP 320 which can redirect the light from the edges and redistribute it evenly towards the plate surface and vice versa. The purpose of this LGP is to enable the LEDs to be positioned at the edges of this layer, so the light can be deflected and spread across the screen. A reflector sheet 310 is responsible for reflecting back any light which is oriented in the opposite direction than the surface of the screen. Two, typically added layers are illustrated: the diffusing layer 330 and the prism sheet 340. These layers redistribute the light more evenly and reflect back misdirected light correspondingly. All other layers and components of the LCD module are illustrated as plate 350, which includes the liquid crystals, the polarizing layers, transparent electrodes etc. Finally, the top surface of the screen, as usual, is a touchscreen module 140. Six LEDs 401 are demonstrated at the edges of the LGP, alongside the solar cells 402 (the actual number of LEDs may vary). The solar cells are electrically connected with the charging mechanism of the instrument. It should be noted that the depicted configuration of the solar cells illustrates that the solar cells should be positioned alongside the edges, facing about these edges and not covering the LEDs themselves. Beside the presented example, any other configuration, which keeps about the basic features, should be feasible. It is demonstrated that the solar cells cover the LGP 320, the diffusing layer 330 and the prism sheet 340 as well. This feature correlates with the interactions of these three layers with light and the preferred proximity between the screen and the solar cells. Any other height of the solar cells is possible while taking into consideration these factors. The entire height and surface area of the screen edges need not all necessarily be covered with solar panels. An exemplified beam of light 230 indicates possible trajectories for the light to reach the solar panels in this configuration. Additional trajectories include the light being reflected from the reflector sheet 310. FIG. 2 demonstrate a top perspective of the same structure 300. All aforementioned layers in this structure are marked as 301 with the adjacent LEDs 401 and solar panels 402, which are positioned alongside the edges of the screen and facing towards it.

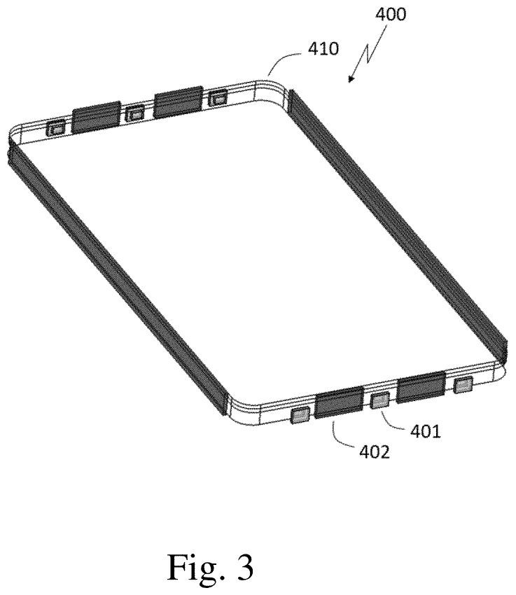

Demonstrating a close up of the three layers of the edge-lit LCD screen with a solar energy utilization functionality 400, FIG. 3 shows the adjacent LGP, diffusing layer and prism sheet 410. These main deflecting layers with the marked operation of the LGP are shown to be surrounded with LEDs 401 and solar panels 402 on the packed form of the screen.

### CLAIMS

The present disclosure of claims will enable a person skilled in the art to manufacture and use the present invention. Such a person will apprehend that changes, modifications and alternations may be applied in form and details, without departing from the spirit and scope of the invention. Hence, the present invention is not intended to be limited to the following disclosure, but to include the scope with all the aforementioned changes.

What is claimed is:

1. A self-rechargeable electronic device with solar cell comprising at least:
a. a screen which includes a light guide plate;
b. at least one solar cell; and
c. a charging mechanism capable of recharging the batteries of the device.
Wherein said solar cells are arranged beside and face about the screen's edges and electrically connected to the charging mechanism of the device.

2. The self-rechargeable electronic device according to claim 1, wherein the mobile device belongs to the group of: smartphone; laptop computer; tablet; e-reader and mobile phone.

3. Edge-lit LCD screen with a solar energy utilization functionality comprising at least:
a. LCD module that includes a light guide plate;
b. at least one solar cell; and
c. at least one light source
Wherein said light sources are positioned adjacent to the edges of the screen, and the solar cells occupy part or all of the remaining space adjacent to the screen's edges and positioned in about a perpendicular way to the screen's largest face.

4. The edge-lit LCD screen according to claim 3, wherein the screen belongs to the following group of devices: smartphones; laptop computers; tablets; e-readers and mobile phones.

5. The edge-lit LCD screen according to claims 3 to 4, wherein said device has an additional mode of function, in which the voltage applied on the liquid crystal layer of the screen's LCD, allows maximal amount of light to go through the LCD module.

6. The edge-lit LCD screen according to claims 3 through 5, wherein the solar cells of the device belong to the following groups of photovoltaic cells: silicon based (amorphous, polycrystalline and single crystalline); GaAs; CdTe; CIGS and organic solar cells.

7. The edge-lit LCD screen according to claims 3 through 6, wherein said screen is a part of the following group of devices: smartphone; laptop computer; tablet; e-reader and mobile phone.

8. The devices according to claims 3 through 7, wherein the device's solar cell contains more than one photoactive layer, in a tandem or multijunction configuration.
